(19) United States
(12) Patent Application Publication
(10) Pub. No.: US 2026/0282333 A1
(43) Pub. Date: Sep. 17, 2026

(54) DRAM DEVICE HAVING 4F2 LAYOUT COMPRISING BIT LINE WITH REDUCED CAPACITANCE

(71) Applicant: TAESUNG ENVIRONMENTAL RESEARCH INSTITUTE CO., LTD., Ulju-gun (KR)

(72) Inventors: Gi Yeol YUN, Ulsan (KR); Seok Man KIM, Ulsan (KR); Chai Rok LIM, Ulsan (KR); Hyeok-Je JEONG, Gimhae-si (KR); Myung-Kon JO, Ulsan (KR); Kwang Ryeol KIM, Ulsan (KR)

(73) Assignee: TAESUNG ENVIRONMENTAL RESEARCH INSTITUTE CO., LTD., Ulju-gun (KR)

(21) Appl. No.: 19/362,948

(22) Filed: Oct. 20, 2025

(30) Foreign Application Priority Data
Jan. 24, 2025 (KR) 10-2025-0011251

(51) Int. Cl. H10B 12/00

(52) U.S. Cl. CPC H10B 12/482; H10B 12/315; H10B 12/488

(57) ABSTRACT

A DRAM device having a 4F2 layout structure, including a plurality of bit lines disposed parallel to each other in a first horizontal direction with a predetermined spacing; a plurality of channel patterns located on the plurality of bit lines and extending in a vertical direction; a plurality of word lines formed on sidewalls of the channel patterns and disposed parallel to each other in a second horizontal direction perpendicular to the first horizontal direction; and a gate insulating pattern located between the plurality of channel patterns and the plurality of word lines; wherein the plurality of bit lines comprises a plurality of first and second bit lines disposed at different heights from each other, and wherein the first and second bit lines are disposed alternately, wherein the plurality of word lines comprises a plurality of first and second word lines disposed at different heights from each other.

### CROSS-REFERENCE TO RELATED APPLICATION

This application claims the benefit of Korean Patent Application No. 10-2025-0011251, filed on Jan. 24, 2025, the entire disclosure of which is incorporated herein by reference in its entirety.

### TECHNICAL FIELD

The present invention relates to a DRAM device, and more particularly, to a DRAM device having a 4F2 layout structure comprising a bit line with reduced capacitance.

### BACKGROUND ART

The operation of a DRAM cell is based on the process of storing and reading data. A DRAM cell generally uses a 1T1C structure composed of one transistor and one capacitor.

A DRAM cell is fundamentally composed of a Capacitor, an Access Transistor, a Bit line, and a Word line.

The capacitor is an element that stores electric charge, and data is stored in the charge state (charged or discharged) of the capacitor.

A positively charged state is a logical ‘1’, and a negatively charged state is a logical ‘0’.

The access transistor is controlled by the word line and provides a path for reading and writing data.

The bit line serves as a path for transferring data, and the word line serves as a signal line for activating or deactivating the access transistor.

Major circuits for the operation of a DRAM cell include a Sense Amplifier, which amplifies the weak signal of the bit line, and Refresh Circuitry, which periodically refreshes the data in the cell.

Meanwhile, the main operational processes of a DRAM cell can be divided into a Write Operation, a Read Operation, and a Refresh Operation.

The write operation is an operation to store data, wherein the word line is activated to turn on the access transistor, input data is transferred to the capacitor through the bit line (in the case of a logical ‘1’, the capacitor is charged with positive charge, and in the case of a logical ‘0’, the capacitor is charged with negative charge), the word line is deactivated to turn off the access transistor, and the data is stored in the capacitor.

The read operation is an operation to read data, wherein the word line is activated to turn on the access transistor, the charge state of the capacitor is transferred to the bit line (if there is positive charge in the capacitor, a slight voltage rise is detected on the bit line, and if there is negative charge in the capacitor, a slight voltage drop is detected on the bit line), and the data on the bit line is amplified by a Sense Amplifier and converted into a readable signal.

Since the capacitor of a DRAM undergoes natural discharge over time, it needs to be periodically refreshed to avoid data loss, and this is called the refresh operation.

The refresh cycle is generally in the order of a few milliseconds (ms), and it replenishes the charge by reading the cell's data and then writing the same data back.

Major characteristics of a DRAM cell include that it is a volatile memory where data is lost when power is cut off as the capacitor's charge is discharged; its simple 1T1C structure allows for high integration density, fast access, and operation with low power; and a periodic refresh cycle is required to maintain data, which consumes additional power.

Key considerations during DRAM cell operation include that as DRAM cells are miniaturized, the capacitor capacitance decreases, making it difficult to store sufficient charge, which can reduce data stability; interference (coupling noise) can occur between adjacent bit lines; and a sufficient margin (sensing margin) is needed to distinguish signals from noise during a read operation.

Through these operations, the DRAM cell stores, reads, and maintains data, performing its role as a high-density and high-performance memory.

Meanwhile, as the integration density of semiconductor memory devices increases, the cell structure is changing from 8F² and 6F² to 4F² in order to reduce the area occupied by each unit cell in a planar manner.

In response to such a reduction in unit cell area, various methods have been proposed for forming components such as transistors, bit lines, word lines, and capacitors.

In particular, a semiconductor device including a vertical channel transistor that induces a vertical channel by arranging the source and drain vertically has been proposed to implement a 4F² cell structure (Non-Patent Document 1).

However, in the semiconductor device of Non-Patent Document 1, channel patterns were disposed at all intersections of the bit lines and word lines, resulting in an excessive number of channel patterns being connected to a single bit line.

As a result, the parasitic capacitance of the bit line increased, making it inevitable to increase the height of the cell capacitor to enhance its capacitance.

Furthermore, the sensing margin of the sense amplifier was reduced. This caused a decrease in the reliability of the semiconductor device and disadvantages in the process.

### PRIOR ART DOCUMENTS

### Non-Patent Documents

(Non-Patent Document 1) Chung et al., “Novel 4F2 DRAM Cell with Vertical Pillar Transistor (VPT)” 2011 Proceedings of the European Solid-State Device Research Conference (ESSDERC), 2011

### DISCLOSURE

### Technical Problem

One of the several objects of the present invention is to provide a vertical channel transistor having a 4F2 layout structure that is highly reliable and easy to manufacture, and a semiconductor device including the same, by achieving an increase in sensing margin and a reduction in cell capacitor height through the reduction of bit line capacitance.

### Technical Solution

According to one aspect, a DRAM device having a 4F2 layout structure is disclosed, the DRAM device comprising: a plurality of bit lines disposed parallel to each other in a first horizontal direction with a predetermined spacing; a plurality of channel patterns located on the plurality of bit lines and extending in a vertical direction; a plurality of word lines formed on sidewalls of the channel patterns and disposed parallel to each other in a second horizontal direction perpendicular to the first horizontal direction; and a gate insulating pattern located between the plurality of channel patterns and the plurality of word lines; wherein the plurality of bit lines comprises a plurality of first and second bit lines disposed at different heights from each other, wherein the first and second bit lines are disposed alternately, wherein the plurality of word lines comprises a plurality of first and second word lines disposed at different heights from each other, wherein the first and second word lines are disposed alternately, wherein the plurality of channel patterns are disposed on the first and second bit lines in an orthogonal grid pattern, wherein a channel pattern located on the first bit line contacts one of the first and second word lines, and a channel pattern located on the second bit line contacts the other of the first and second word lines.

In one embodiment, a channel pattern located on the first bit line may contact the first word line, and a channel pattern located on the second bit line may contact the second word line.

In one embodiment, the separation distance between the first bit line and the first word line and the separation distance between the second bit line and the second word line may be the same.

In one embodiment, the separation distance between adjacent first and second bit lines and the separation distance between adjacent first and second word lines may each be 1.5 times the minimum feature size (1F) or less.

In one embodiment, the DRAM device may have a folded bit line structure.

In one embodiment, each of the plurality of channel patterns may include an upper electrode and a lower electrode, and the lower electrode may contact the bit line.

In one embodiment, the device may further comprise a gate conductive pattern provided between the word line and the gate insulating pattern.

### Advantageous Effects

The vertical channel transistor and the semiconductor device including the same according to the present invention can increase the sensing margin of a sense amplifier due to the lowered parasitic capacitance of the bit line, thereby having the advantage of excellent reliability.

In addition, the vertical channel transistor and the semiconductor device including the same according to the present invention allow for a reduction in the height of the cell capacitor, which is advantageous for ease of manufacturing and scaling down.

The effects of one aspect of the present invention are not limited to the effects mentioned above, and it should be understood that all effects that can be inferred from the configurations described in the detailed description or claims of this specification are included.

### DESCRIPTION OF DRAWINGS

FIG. 1 is a perspective view of a vertical channel transistor according to an embodiment of the present invention.

FIG. 2 is a cross-sectional view taken along the line A-A′ of FIG. 1.

FIG. 3 is a cross-sectional view taken along the line B-B′ of FIG. 1.

FIG. 4 is a perspective view of a semiconductor device including a vertical channel transistor according to an embodiment of the present invention.

FIG. (a) of FIG. 5 is a plan view of a conventional DRAM device including a vertical channel transistor with a 4F² structure, and FIG. (b) of FIG. 5 is a plan view of a DRAM device including a vertical channel transistor in which (3) the spacing between adjacent word lines is reduced to half (½) compared to (1) the width of the word lines, (2) the width of the bit lines, and (4) the spacing between adjacent bit lines.

### MODES OF THE INVENTION

Hereinafter, one aspect of the present specification will be described with reference to the accompanying drawings.

However, the descriptions in this specification can be implemented in many different forms and are not limited to the embodiments described herein.

Throughout this specification, when a part is referred to as being “connected” to another part, this includes not only cases where they are “directly connected” but also cases where they are “indirectly connected” with another member in between.

In addition, when a member is referred to as being located “on,” “above,” “on top of,” “under,” “below,” or “at the bottom of” another member, this includes not only cases where the members are in contact but also cases where another member exists between the two members.

Throughout this specification, when a part is said to “comprise” a certain component, it means that it may further include other components, rather than excluding them, unless otherwise stated.

The embodiments described in this specification will be explained with reference to cross-sectional views and/or perspective views that are ideal exemplary diagrams of the present invention.

In addition, throughout the specification, the same reference numerals refer to the same constituent elements.

At this time, detailed descriptions of known functions and configurations that may obscure the gist of the present invention have been omitted.

And, in each drawing shown in the present invention, each component may be shown somewhat enlarged or reduced for convenience of explanation.

Furthermore, the embodiments of the present invention are not limited to the specific shapes shown but also include changes in shape that may be generated according to the manufacturing process.

Hereinafter, preferred embodiments of the present invention will be described in detail with reference to the accompanying drawings.

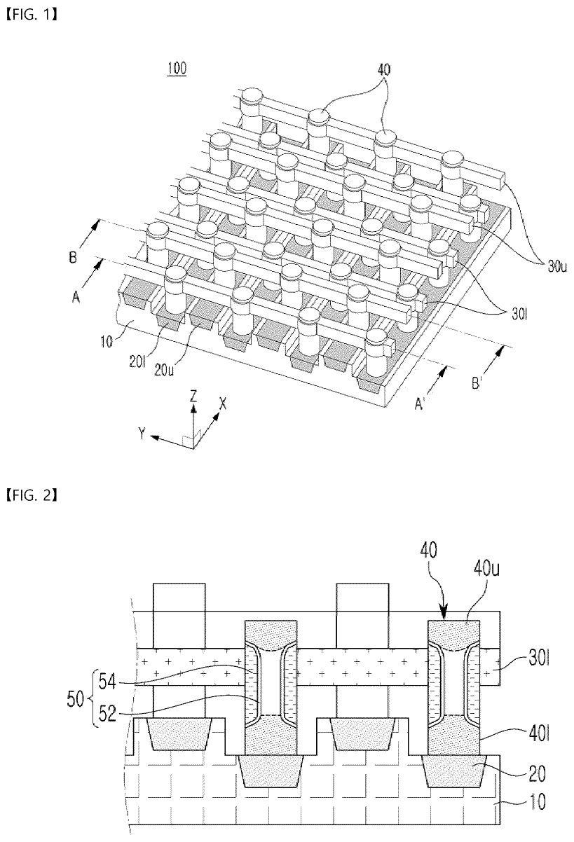

FIG. 1 is a perspective view schematically illustrating a vertical channel transistor according to an embodiment of the present invention.

Referring to FIG. 1, a vertical channel transistor (100) according to an embodiment of the present invention has a 4F² layout structure and comprises: a plurality of bit lines (20) disposed parallel to each other in a first horizontal direction with a predetermined spacing;
a plurality of channel patterns (40) located on the plurality of bit lines (20) and extending in a vertical direction;
a plurality of word lines (30) formed on sidewalls of the channel patterns (40) and disposed parallel to each other in a second horizontal direction perpendicular to the first horizontal direction;
and a gate insulating pattern (not shown) located between the plurality of channel patterns (40) and the plurality of word lines (30).

In the vertical channel transistor (100) according to an embodiment of the present invention, the plurality of bit lines (20) and the plurality of word lines (30) are provided to intersect each other.

Each bit line (20) may be provided to extend in a first horizontal direction (e.g., the x-axis direction), and each word line (30) may be provided to extend in a second horizontal direction perpendicular to the first horizontal direction (e.g., the y-axis direction).

Among the points where the plurality of bit lines (20) and the plurality of word lines (30) intersect, a plurality of channel patterns (40) extending in a vertical direction (e.g., the z-axis direction) are disposed on the bit lines (20) in an orthogonal grid pattern.

In a conventional vertical channel transistor, channel patterns were disposed at all intersections of the plurality of bit lines (20) and the plurality of word lines (30).

As a result, the parasitic capacitance of the bit line increased, making it inevitable to increase the height of the cell capacitor to enhance its capacitance.

Furthermore, the sensing margin of the sense amplifier was reduced. This caused a decrease in the reliability of the semiconductor device and disadvantages in the process.

However, in the present invention, since the plurality of channel patterns (40) are disposed at only some of the intersection points of the plurality of bit lines (20) and the plurality of word lines (30), the number of channel patterns disposed on a single bit line is reduced, and the number of cell transistors is reduced, thereby lowering the parasitic capacitance of the bit line.

As a result, the sensing margin of the sense amplifier is increased, or the height of the cell capacitor can be lowered, which is advantageous for increasing reliability, easing manufacturing, and facilitating scaling down.

Furthermore, in the present invention, since neighboring bit lines do not share word lines with each other, a cell array with a folded bit line structure becomes possible, which is an advantage.

With a folded bit line structure, data sensing can be performed stably, the size of the cell array can be increased, and the sense amplifier area can be reduced, which can be advantageous in terms of cell efficiency.

The plurality of bit lines (20) comprises a plurality of first bit lines (20l) and second bit lines (20u) disposed at different heights from each other, and the first and second bit lines (20l and 20u) are disposed alternately.

The plurality of word lines (30) comprises a plurality of first word lines (30l) and second word lines (30u) disposed at different heights from each other, and the first and second word lines (30l and 30u) are disposed alternately.

A channel pattern (40) located on the first bit line (20l) contacts one of the first and second word lines (30l and 30u), and a channel pattern (40) located on the second bit line (20u) contacts the other of the first and second word lines (30l and 30u).

In conventional vertical channel transistors, a plurality of bit lines and word lines were arranged side by side at substantially the same height, posing a physical limit to increasing the capacity per unit area.

However, in the present invention, since adjacent bit lines and word lines are each disposed at different heights, the minimum feature size F can be easily reduced, and as a result, there is an advantage in that the capacity per unit area and the integration density can be increased.

In particular, in the present invention, a 4F² layout structure can be achieved even though the channel patterns (40) are disposed only at some of the intersection points of the plurality of bit lines (20) and the plurality of word lines (30), because the adjacent bit lines and word lines are each disposed at different heights. The reason for this will be explained in more detail as follows.

In the field of DRAM devices, the minimum feature size F is an important factor that determines the integration density and performance of the device.

The minimum feature size F refers to the smallest line width that can be drawn within a semiconductor circuit, and it generally means the smallest of (1) the width of a word line, (2) the width of a bit line, (3) the spacing between adjacent word lines, and (4) the spacing of adjacent bit lines.

As the minimum feature size F becomes smaller, the transistor density of a semiconductor chip increases, the chip size decreases, and power consumption is reduced. Therefore, technological development in the DRAM device field is moving in the direction of adopting the smallest possible minimum feature size F.

However, this minimum feature size F cannot be reduced indefinitely and is typically determined by the level of technological development at the time of manufacturing.

Specifically, it is determined by factors such as the resolution of photolithography equipment and the quality and performance of photoresist.

FIG. (a) of FIG. 5 is a plan view of a DRAM device including a conventional vertical channel transistor having a 4F² layout structure.

In FIG. (a) of FIG. 5, (1) the width of the word line, (2) the width of the bit line, (3) the spacing between adjacent word lines, and (4) the spacing between adjacent bit lines are all set to F, and accordingly, it has a 4F² layout structure.

FIG. (b) of FIG. 5 is a plan view of a DRAM device including a vertical channel transistor in which (3) the spacing between adjacent word lines is reduced to half (½) compared to (1) the width of the word line, (2) the width of the bit line, and (4) the spacing between adjacent bit lines.

In this case, (3) the spacing between adjacent word lines becomes the minimum feature size F, and since this minimum feature size F is determined by the level of technological development at the time of manufacturing, it ultimately results in an increase in the area of the unit cell (12F²=4F*3F).

That is, the method of adjusting the spacing between adjacent word lines or bit lines to reduce the unit cell area is by no means desirable.

However, in the present invention, as long as the spacing between adjacent first bit lines (20l) and the spacing between adjacent second bit lines (20u) are each greater than or equal to the minimum feature size F, the horizontal spacing between the adjacent first and second bit lines (20l and 20u) can be adjusted to any value.

Also, in the present invention, as long as the spacing between adjacent first word lines (30l) and the spacing between adjacent second word lines (30u) are each greater than or equal to the minimum feature size F, the horizontal spacing between the adjacent first and second word lines (30l and 30u) can be adjusted to any value.

This is because word lines formed on different planes (at different heights) are formed in different process steps, and thus are not affected by the minimum feature size determined by the technology level at the time of manufacturing.

Theoretically, the horizontal spacing between adjacent first and second bit lines and the horizontal spacing between adjacent first and second word lines can be adjusted down to ½F each.

Therefore, the DRAM device according to one aspect of the present invention has the advantage of achieving an improved capacity per unit area compared to the capacity per unit area that can generally be achieved at the level of technical progress at the time of manufacture.

According to one example, the separation distance between adjacent first and second bit lines and the separation distance between adjacent first and second word lines may each be 1.5 times the minimum feature size (1F) or less, and through this, a 4F² layout structure or a sub-4F² structure (e.g., a 3.5F² structure) layout can be achieved.

According to one example, the channel pattern (40) located on the first bit line (20l) may contact the first word line (30l), and the channel pattern (40) located on the second bit line (20u) may contact the second word line (30u).

When the first bit line (20l) and the first word line (30l) intersect each other, and the second bit line (20u) and the second word line (30u) intersect each other in this way, the resistance distribution in the data path of the channel pattern (40) becomes uniform, which can reduce the defect rate.

According to one example, the separation distance between the first bit line (20l) and the first word line (30l) and the separation distance between the second bit line (20u) and the second word line (30u) may be substantially the same.

Here, the separation distance means the length of a line segment connecting the center of the first or second bit line and the center of the first or second word line when a virtual line extended in the vertical direction (e.g., the z-axis direction) is drawn at an arbitrary point.

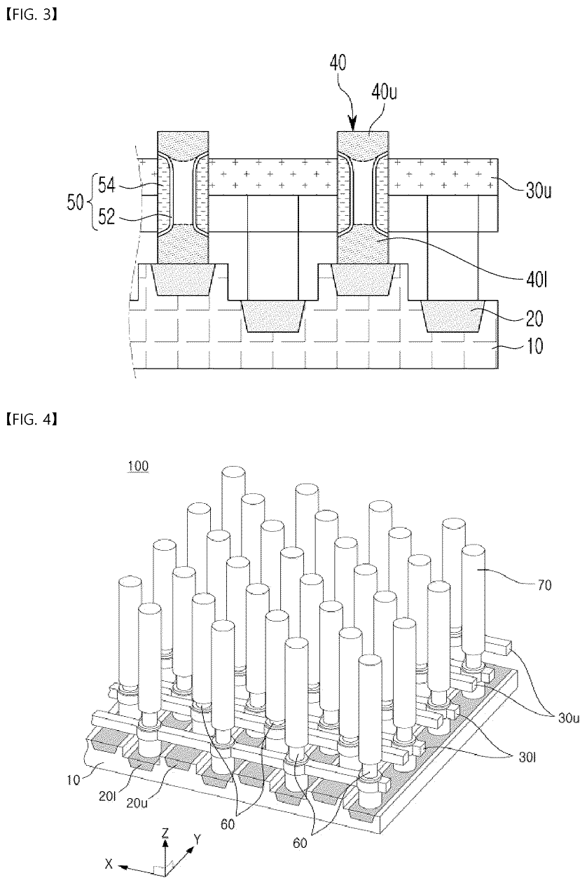

FIG. 2 is a cross-sectional view taken along the line A-A′ of FIG. 1.

The substrate (10) may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, an oxynitride semiconductor, or the like.

Specifically, the substrate may be a silicon substrate doped with n-type impurities, but is not limited thereto.

Each of the plurality of channel patterns (40) may be provided to extend substantially vertically from the substrate (10).

Here, each channel pattern (40) may be provided to protrude substantially vertically from the upper surface of the substrate (10).

Each channel pattern (40) may be formed integrally with the substrate (10), thereby including the same semiconductor material as the substrate (10).

Each of the plurality of channel patterns (40) may include an upper electrode (40u) as a source region and a lower electrode (40l) as a drain region.

The lower electrode (40l) is electrically connected to the bit line (20), and the upper electrode (40u) may be electrically connected to a capacitor (not shown), which will be described later.

The positions of the source region and the drain region may be changed as needed, and the upper electrode (40u) may function as a drain region, and the lower electrode (40l) may function as a source region.

In the channel pattern (40), the region between the upper electrode (40u) and the lower electrode (40l) is a body region (not shown) and has the same polarity as the substrate (10), while the upper electrode (40u) and the lower electrode (40l) have a different polarity from the substrate (10).

For example, if the substrate (10) is a p-type semiconductor substrate, the body region has a p-type polarity, and the upper electrode (40u) and the lower electrode (40l) have an n-type polarity.

In this case, the upper electrode (40u) and the lower electrode (40l) can be formed by implanting n-type impurity ions into the top and bottom of the channel pattern (40), respectively, and performing drive-in diffusion.

A gate (50) is formed to surround the side surface of the channel pattern (40) between the upper and lower electrodes, and the gate (50) may be composed of a gate insulating pattern (52) and a gate conductive pattern (54).

According to an example, at least a portion of each channel pattern (40) may be in direct contact with the substrate (10), in which case a back bias can be delivered to each channel pattern (40) to suppress the floating body effect phenomenon.

The contact portion of each channel pattern (40) and the substrate (10) is not particularly limited, but for example, it may be either the outer part or the central part of each channel pattern (40).

The first bit line (20l) is provided to extend along the first horizontal direction (e.g., the x-axis direction) below the lower electrode (40l), and each first bit line (20l) can electrically connect the lower electrodes (40l) arranged along the first horizontal direction.

The first bit line (20l) is formed inside the substrate (10) and may thereby include the same semiconductor material as the substrate (10).

Each of the plurality of first word lines (30l) is provided at a height corresponding to the gate (50) formed on the side of the channel pattern (40).

In addition, each first word line (30l) is provided to surround at least a portion of the gate (50).

The first word line (30l) may include a conductive material. For example, the first word line (30l) may include at least one of a metal, a semiconductor, and an alloy.

Specifically, the first word line (30l) may include one or more metals selected from the group consisting of aluminum, tungsten, molybdenum, titanium, and tantalum, or one or more semiconductors selected from the group consisting of group IV semiconductors, group III-V semiconductors, oxide semiconductors, nitride semiconductors, and oxynitride semiconductors, but is not limited thereto.

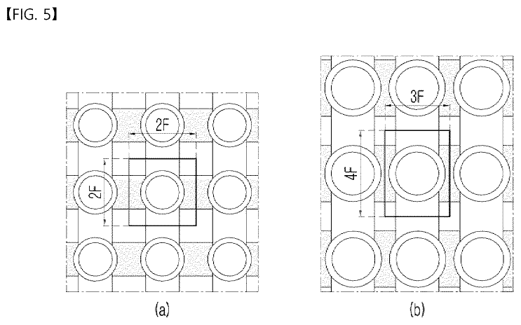

FIG. 3 is a cross-sectional view taken along the line B-B′ of FIG. 1.

The second bit line (20u) is provided to extend along the first horizontal direction (e.g., the x-axis direction) below the lower electrode (40l), and each second bit line (20u) can electrically connect the lower electrodes (40l) arranged along the first horizontal direction.

The second bit line (20u) is formed inside the substrate (10) and may thereby include the same semiconductor material as the substrate (10).

The second bit line (20u) is disposed at a different height from the first bit line (20l) when viewed in a vertical cross-section, and specifically, the second bit line (20u) is disposed at a higher position than the first bit line (20l).

As the adjacent first and second bit lines (20l and 20u) are disposed at different heights in this way, the minimum feature size F can be easily reduced, and as a result, there is an advantage in that the capacity per unit area and the integration density can be increased.

The plurality of channel patterns (40) are commonly connected to the second word line (30u), and specifically, each second word line (30u) is provided at a height corresponding to the gate (50) formed on the side of the channel pattern (40).

In addition, each second word line (30u) is provided to surround at least a portion of the gate (50).

The second word line (30u) is disposed at a different height from the first word line (30l) when viewed in a vertical cross-section, and specifically, the second word line (30u) is disposed at a higher position than the first word line (30l).

As the adjacent first and second word lines (30l and 30u) are disposed at different heights in this way, the minimum feature size F can be easily reduced, and as a result, there is an advantage in that the capacity per unit area and the integration density can be increased.

FIG. 4 is a perspective view schematically showing a semiconductor device including a vertical channel transistor according to an embodiment of the present invention.

Referring to FIG. 4, a capacitor (70) is connected on the vertical channel transistor (100), through which a semiconductor device (200) such as a DRAM can be implemented.

The capacitor (70) can be electrically connected to the channel pattern (40), and a contact plug (60) may be further included between the capacitor (70) and the channel pattern (40).

The vertical channel transistor (100) can be utilized not only in memory as described above but also in non-memory such as a central processing unit (CPU).

The present invention does not particularly limit the manufacturing method of the vertical channel transistor and the semiconductor device including the same, but they can be manufactured, for example, by the following method.

A substrate is prepared in which protrusions and recesses are alternately provided in a first horizontal direction (e.g., the x-axis direction).

The protrusions and recesses may be formed extending in a second horizontal direction.

On the substrate (10), a plurality of channel patterns (40) are formed, in which electrodes (40u and 40l) are formed at the top and bottom, and which extend in a substantially vertical direction.

The plurality of channel patterns (40) are formed in each of the protrusions and recesses. The upper electrode (40u) of the plurality of channel patterns may be, for example, a source region, and the lower electrode (40l) of the plurality of channel patterns may be, for example, a drain region.

The plurality of channel patterns (40) may be arranged in a two-dimensional array form on the plane of the substrate (10) (e.g., the xy plane), and specifically, may be disposed in an orthogonal grid pattern.

Next, a gate (50) is formed to surround the side surface between the upper electrode (40u) and the lower electrode (40l) of the plurality of channel patterns (40).

The gate (50) may include a gate insulating pattern (52) and a gate conductive pattern (54).

Next, a plurality of bit lines (20) are formed to be in common contact with the lower electrodes (40l) of the plurality of channel patterns (40).

In this case, a first bit line (20l) is formed below the channel patterns (40) formed in the recesses, and a second bit line (20u) is formed below the channel patterns (40) formed on the protrusions.

Next, a plurality of first and second word lines (30l and 30u) are formed to be in common contact with the gates (50) formed on the sides of the plurality of channel patterns (40).

The first and second word lines (30l and 30u) may be formed in the first horizontal direction (e.g., the x-axis direction) and may be provided alternately in the second horizontal direction (e.g., the y-axis direction).

Each of the first and second word lines (30l and 30u) passes through the center of the plurality of channel patterns (40) arranged in a straight line in the first horizontal direction (e.g., the x-axis direction).

Thereafter, a series of known subsequent processes are sequentially performed to complete the manufacture of the vertical channel transistor and the semiconductor device including the same according to the present invention.

The foregoing description of the present specification is for illustrative purposes, and those of ordinary skill in the art to which one aspect of the present specification pertains will be able to understand that modifications to other specific forms are easily possible without changing the technical spirit or essential features described in the present specification.

Therefore, it should be understood that the embodiments described above are illustrative in all respects and not restrictive.

For example, each component described as a single unit may be implemented in a distributed manner, and likewise, components described as distributed may also be implemented in a combined form.

The scope of the present specification is indicated by the claims described below, and all changes or modified forms derived from the meaning and scope of the claims and their equivalent concepts should be interpreted as being included in the scope of the present specification.

### DESCRIPTION OF THE REFERENCE NUMERALS

| | |
|---|---|
| 10: Substrate | 20: Bit line |
| 20l: First bit line | 20u: Second bit line |
| 30: Word line | 30l: First word line |
| 30u: Second word line | 40: Channel pattern |
| 40l: Lower electrode | 40u: Upper electrode |
| 50: Gate | 52: Gate insulating pattern |
| 54: Gate conductive pattern | 60: Contact plug |
| 70: Capacitor | 100: Vertical channel transistor |
| 200: DRAM device | |

1. A DRAM device having a 4F2 layout structure, comprising: a plurality of bit lines disposed parallel to each other in a first horizontal direction with a predetermined spacing;
a plurality of channel patterns located on the plurality of bit lines and extending in a vertical direction;
a plurality of word lines formed on sidewalls of the channel patterns and disposed parallel to each other in a second horizontal direction perpendicular to the first horizontal direction; and
a gate insulating pattern located between the plurality of channel patterns and the plurality of word lines;
wherein the plurality of bit lines comprises a plurality of first and second bit lines disposed at different heights from each other, and wherein the first and second bit lines are disposed alternately,
wherein the plurality of word lines comprises a plurality of first and second word lines disposed at different heights from each other, and wherein the first and second word lines are disposed alternately,
wherein the plurality of channel patterns are disposed on the first and second bit lines in an orthogonal grid pattern,
and wherein a channel pattern located on the first bit line contacts the first word line, and a channel pattern located on the second bit line contacts the second word line.

2. The DRAM device according to claim 1,
wherein the separation distance between the first bit line and the first word line and the separation distance between the second bit line and the second word line are the same.

3. The DRAM device according to claim 1,
wherein a separation distance between adjacent first and second bit lines and a separation distance between adjacent first and second word lines are each 1.5 times a minimum feature size (1F) or less.

4. The DRAM device according to claim 1,
wherein the DRAM device has a folded bit line structure.

5. The DRAM device according to claim 1,
wherein each of the plurality of channel patterns comprises an upper electrode and a lower electrode, and wherein the lower electrode contacts the bit line.

6. The DRAM device according to claim 1,
further comprising: a gate conductive pattern provided between the word line and the gate insulating pattern.
